(19) United States
(12) Patent Application Publication
(10) Pub. No.: US 2020/0381578 A1
(43) Pub. Date: Dec. 3, 2020

(54) MANUFACTURING METHOD OF THIN FILM SOLAR CELL AND THIN FILM SOLAR CELL

(71) Applicant: TRUWIN OPTO-ELECTRONICS LIMITED, Guang Dong (CN)

(72) Inventors: Yuan LI, Guangdong (CN); Yun ZHAO, Guangdong (CN); Weicang ZHANG, Guangdong (CN); Bin SUI, Guangdong (CN); Wenjin ZHANG, Guangdong (CN); Liang YANG, Guangdong (CN)

(73) Assignee: TRUWIN OPTO-ELECTRONICS LIMITED, Guang Dong (CN)

(21) Appl. No.: 16/770,082

(22) PCT Filed: Jun. 3, 2019
(86) PCT No.: PCT/CN2019/089806

§ 371 Date: Aug. 20, 2020

(30) Foreign Application Priority Data
May 28, 2019 (CN) 201910452515.8

(51) Int. Cl. H01L 31/18; H01L 31/0216; H01L 31/0224

(52) U.S. Cl. CPC H01L 31/1884; H01L 31/022466; H01L 31/022425; H01L 31/02168

(57) ABSTRACT

The present disclosure provides a thin film solar cell and a manufacturing method thereof. The thin film solar cell includes a transparent substrate and a photovoltaic unit disposed on the transparent substrate and facing a display module. The photovoltaic unit includes a front electrode disposed on the transparent substrate, a light absorption layer disposed on the front electrode, and a back electrode disposed on the light absorption layer. The thin film solar cell further includes a metal auxiliary electrode and an insulating layer. The insulating layer covers the back electrode and the light absorption layer, and extends to be in contact connection with the front electrode. The metal auxiliary electrode is in contact connection with the front electrode, and extends onto the insulating layer. A taper angle is formed between a periphery of the insulating layer and the front electrode, and the taper angle ranges from 35° to 75°.

### BACKGROUND

### Technical Field

The present disclosure relates to the technical field of solar cell manufacturing, and more particularly relates to a manufacturing method of a thin film solar cell and the thin film solar cell.

### Description of Related Art

With the advancement of technologies and the urgent need to solve energy problems, solar cells are widely researched and used as energy conversion devices. For example, the solar cells are applied to displayable electronic products (such as wearable devices). Generally, an electronic product includes a frame region and a middle display region. According to displayed appearance features of the products, a design method of a single cell or a plurality of cells connected in series will be used. At the same time, in order to improve the photovoltaic conversion efficiency of the cells, a photovoltaic conversion unit will also be usually disposed in a display region. However, in order to consider both the light transmittance and the visual effect of the display region, the width of the photovoltaic conversion unit in the display region would be designed to be very narrow, and the width of a metal electrode is generally about 10 m.

Since the width is designed to be very narrow, different manufacturing processes have a great impact on an effective area of the photovoltaic conversion unit and the reliability of the products.

### SUMMARY

In order to solve the deficiencies in the prior art, the present disclosure provides a manufacturing method of a thin film solar cell and the thin film solar cell. By forming a taper angle between a periphery of an insulating layer and a front electrode, the taper angle ranges from 35° to 75° so that it can be simultaneously ensured that a maximum photovoltaic absorption area and the lowest reflection visibility of a metal auxiliary electrode are obtained, and the reliability of a product is simultaneously ensured.

The technical effects to be achieved by the present disclosure are achieved through the following solution: a manufacturing method of a thin film solar cell, including the following steps:

Step S100: providing a transparent substrate, and stacking a front electrode, a light absorption layer and a back electrode on one side of the transparent substrate facing a display module in sequence to form a film;

Step S200: etching the back electrode, the light absorption layer and the front electrode in sequence;

Step S300: manufacturing an insulating layer by the film-forming, wherein the insulating layer covers the back electrode and the light absorption layer and extends to be in contact connection with the front electrode; and

Step S400: performing film formation and etching on a metal auxiliary electrode on the insulating layer, wherein the metal auxiliary electrode extends to be in contact with the front electrode.

In the manufacturing process of the insulating layer, a taper angle is formed between a periphery of the insulating layer and the front electrode, and the taper angle ranges from 35° to 75°.

Preferably, in the step S200, the back electrode and the light absorption layer are further perforated to form a via hole region. In the step S300, the insulating layer extends to be in contact with the front electrode in the via hole region.

Preferably, the insulating layer is not fully filled in the via hole region, so that the metal auxiliary electrode is in contact with the front electrode in the via hole region.

Preferably, before the front electrode is manufactured, the method further includes: manufacturing a cover layer of an inter-cell dividing line of the transparent substrate.

Preferably, after the metal auxiliary electrode is manufactured, the method further includes: manufacturing an anti-reflection layer. The anti-reflection layer covers the metal auxiliary electrode.

A thin film solar cell includes a transparent substrate and a photovoltaic unit disposed on the transparent substrate and facing a display module. The photovoltaic unit includes a front electrode disposed on the transparent substrate, a light absorption layer disposed on the front electrode, and a back electrode disposed on the light absorption layer. The thin film solar cell further includes a metal auxiliary electrode and an insulating layer. The insulating layer covers the back electrode and the light absorption layer, and extends to be in contact connection with the front electrode. The metal auxiliary electrode is in contact connection with the front electrode, and extends onto the insulating layer. A taper angle is formed between a periphery of the insulating layer and the front electrode, and the taper angle ranges from 35° to 75°.

Preferably, the back electrode and the light absorption layer are further perforated to form a via hole region, and the insulating layer is in contact connection with the front electrode in the via hole region.

Preferably, the insulating layer is not fully filled in the via hole region, and the metal auxiliary electrode is in contact with the front electrode in the via hole region.

Preferably, an anti-reflection layer is further disposed on the metal auxiliary electrode. The anti-reflection layer covers the metal auxiliary electrode.

The present disclosure has the following advantages:

1. By forming the taper angle between the periphery of the insulating layer and the front electrode, the taper angle ranges from 35° to 75° so that it can be simultaneously ensured that a maximum photovoltaic absorption area and the lowest reflection visibility of the metal auxiliary electrode are obtained, and the reliability of a product is simultaneously ensured.

2. By perforating the back electrode and the light absorption layer to form the via hole region, the insulating layer is not fully filled in the via hole region, so that the metal auxiliary electrode is in contact with the front electrode in the via hole region, which can further reduce the resistance of the front electrode.

### BRIEF DESCRIPTION OF THE DRAWINGS

FIG. 1 is a planar structural schematic diagram of a thin film solar cell in the present disclosure;

FIG. 2 is a sectional structural schematic diagram 1 (a large taper angle) according to one implementation mode at position A-A in FIG. 1;

FIG. 3 is a sectional structural schematic diagram 2 (a small taper angle) according to one implementation mode at position A-A in FIG. 1;

FIG. 4 is a sectional structural schematic diagram 1 (a large taper angle) according to another implementation mode at position A-A in FIG. 1; and

FIG. 5 is a sectional structural schematic diagram 2 (a small taper angle) according to another implementation mode at position A-A in FIG. 1.

### DESCRIPTION OF THE EMBODIMENTS

The present disclosure will be described in detail below with reference to the accompanying drawings and embodiments. Examples of the embodiments are shown in the drawings, in which the same or similar reference numerals indicate the same or similar elements or elements with the same or similar functions from beginning to end. The embodiments described below with reference to the drawings are exemplary, and are intended to explain the present disclosure, and should not be construed as limiting the present disclosure.

In the description of the present disclosure, it should be understood that orientations or positional relationships indicated by the terms “length”, “width”, “upper”, “lower”, “front”, “rear”, “left”, “right”, “vertical”, “horizontal”, “top”, “bottom”, “inside”, “outside” and the like are orientations or positional relationships as shown in the drawings, and are only for the purpose of facilitating and simplifying the description of the present invention instead of indicating or implying that devices or elements indicated must have particular orientations, and be constructed and operated in the particular orientations, so that the terms cannot be construed as limiting the present disclosure.

In the present disclosure, unless otherwise clearly specified and defined, the terms “installation”, “connected”, “coupled”, “fixed”, “disposed” and the like should be understood in a broad sense, for example, it can be a fixed connection, a detachable connection, or integrated. It can be a mechanical connection or an electrical connection. It can be a direct connection, or an indirect connection through an intermediate medium. It can also be an internal communication between two components or the interaction between the two components. For those of ordinary skill in the art, the specific meanings of the above terms in the present disclosure can be understood according to specific situations.

### Embodiment I

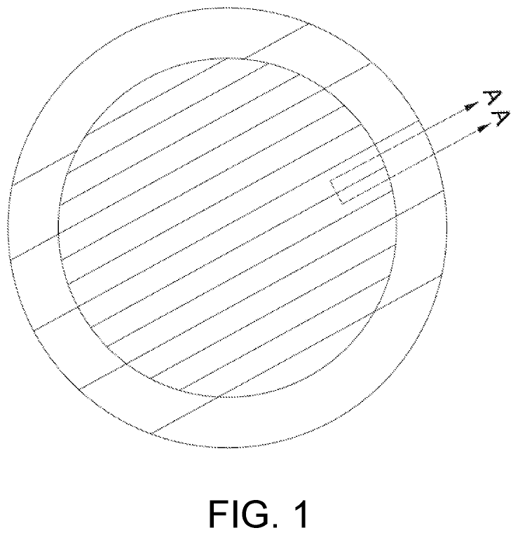

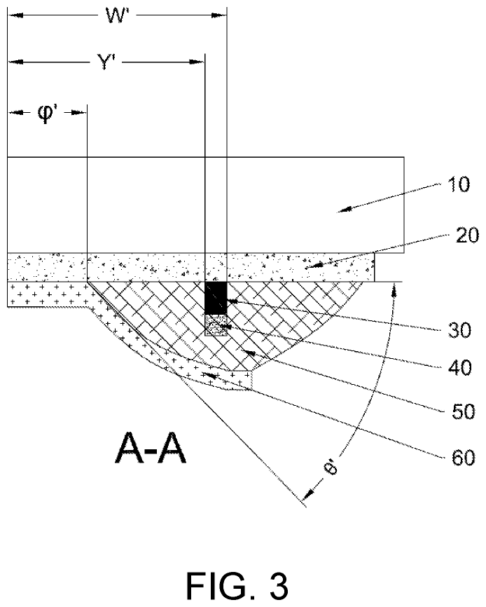

As shown in FIG. 1 to FIG. 3, an embodiment of the present disclosure provides a manufacturing method of a thin film solar cell. The thin film solar cell includes a transparent substrate 10 and a photovoltaic unit disposed on the transparent substrate 10 and facing a display module. The photovoltaic unit includes a front electrode 20 disposed on the transparent substrate, a light absorption layer 30 disposed on the front electrode 20, and a back electrode 40 disposed on the light absorption layer 30. The thin film solar cell further includes an insulating layer 50 and a metal auxiliary electrode 60. The insulating layer 50 covers the back electrode 40 and the light absorption layer 30, and extends to be in contact connection with the front electrode 20. The metal auxiliary electrode 60 is in contact connection with the front electrode 20, and extends onto the insulating layer 50.

A manufacturing method of the thin film solar cell includes the following steps:

Step S100: a transparent substrate 10 is provided, and a front electrode 20, a light absorption layer 30 and a back electrode 40 are stacked on one side of the transparent substrate 10 facing a display module in sequence to form a film.

Optionally, the manufacturing method further includes a step that the front electrode 20 is textured to form a rugged plane, so as to enhance solar energy absorption. A stacking film formation process of the front electrode 20, the light absorption layer 30 and the back electrode 40 is an existing conventional technology, and no specific limitation is made.

Step S200: the back electrode 40, the light absorption layer 30 and the front electrode 20 are subjected to etched imaging in sequence.

The etched imaging in the step S200 is performed from top to bottom, that is, the back electrode 40, the light absorption layer 30 and the front electrode 20 are subjected to etched imaging in sequence. In this way, performance of the back electrode 40, the light absorption layer 30 and the front electrode 20 can be ensured, and damage in the etching process to other layers can be prevented.

Step S300: an insulating layer 50 is manufactured by the film-forming on the back electrode 40, wherein the insulating layer 50 covers the back electrode 40 and the light absorption layer 30 and extends to be in contact connection with the front electrode 20. The insulating layer 50 is configured to protect the back electrode 40 and the light absorption layer 30, and can prevent a short circuit caused by contact between the back electrode 40 and the front electrode 20.

Step S400: film formation and etching are performed on a metal auxiliary electrode 60 on the insulating layer 50, wherein the metal auxiliary electrode 60 extends to be in contact with the front electrode 20.

In the manufacturing process of the insulating layer 50, a taper angle is formed between a periphery of the insulating layer 50 and the front electrode 20, and the taper angle ranges from 35° to 75°.

By the setting of the angle range of the taper angle of the insulating layer, it can be simultaneously ensured that a maximum photovoltaic absorption area and the lowest reflection visibility of the metal auxiliary electrode 60 are obtained.

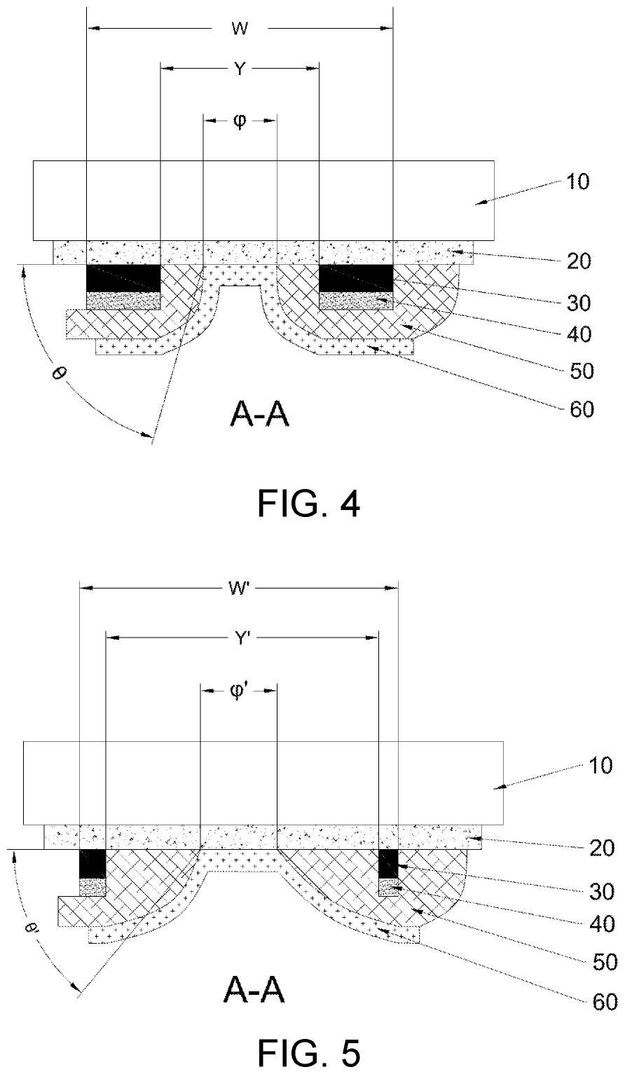

As shown in FIG. 4 to FIG. 5, as a further improvement of the present disclosure, in the step S200, the back electrode 40 and the light absorption layer 30 are also perforated to form a via hole region, and in the step S300, the insulating layer 50 extends to be in contact with the front electrode 20 in the via hole region. The perforation step may be that this region is etched away by using a mask plate in the process of etching the back electrode 40 and the light absorption layer 30 to form a via hole, but it is not limited to this.

As a further improvement of the present disclosure, the insulating layer 50 is not fully filled in the via hole region to cause the metal auxiliary electrode 60 to be in contact with the front electrode 20 in the via hole region. In this way, a contact area of the metal auxiliary electrode 60 and the front electrode 20 can be enlarged, and the resistance of the front electrode 20 can be further reduced.

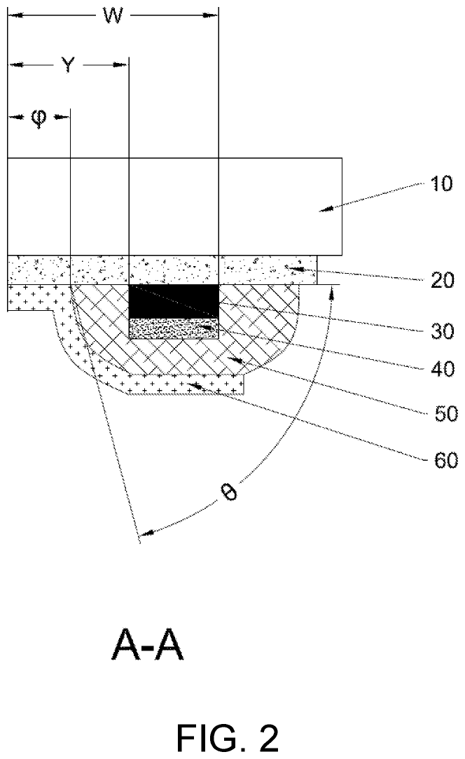

A formation principle of the taper angle between the insulating layer 50 and the transparent substrate 10 is as follows. Referring to FIG. 2 to FIG. 5, it is assumed that a total width of the photovoltaic unit is W/W′, and a width of the outer edge (or the via hole region) of the photovoltaic unit, which is not provided with the front electrode 20 and the light absorption layer 30, is γ/γ′. When a design value (a contact width or the size p of the via hole) of the contact area of the metal auxiliary electrode 60 and the front electrode is fixed, the size of the taper angle (θ/θ′) of the insulating layer 50 is a key influence factor that affects the contact reliability of the metal auxiliary electrode 60 and the front electrode at the outer edge (or in the via hole region) of the photovoltaic unit. At the same time, the taper angle is also a main factor that affects the area of the light absorption layer 30 around the outer edge (or the via hole region) of the photovoltaic unit. If θ is larger, an effective area of photovoltaic absorption maintained around is larger. However, after the θ value exceeds 75°, a metal deposition layer of the metal auxiliary electrode 60 at the outer edge of the photovoltaic unit of the front electrode 20 (or at the circumference of the bottom surface of the via hole region) is thinner and is poorer in overlapping effect (there are crystalline grains stacked in a staggering manner at interfaces of different planes). On the contrary, if the taper angle is smaller, the metal deposition layer of the metal auxiliary electrode 60 at the outer edge of the photovoltaic unit of the front electrode 20 (or at the circumference of the bottom surface of the via hole region) is thicker and is better in overlapping effect (the stacking and overlapping state of the crystalline grains is close to the effect in a plane region), and the overlapping effect with the front electrode 20 will also be better. However, in order to completely cover the back electrode 40 (the coating thickness of the insulating layer 50 shall be large enough when the total stacking thickness of the light absorption layer 30 and the back electrode 40 is kept unchanged) and also keep the effective width of photovoltaic absorption around unchanged [(W−γ)=(W′−γ′)], the size of a photovoltaic absorption layer at this position needs to be widened. Meanwhile, as the θ value decreases, a metal reflection area at an outer edge (or in the via hole region) region of the photovoltaic unit is multiplied therewith, so that it is more and more apparent to identify a metal from the side of the transparent substrate 10. In order to guarantee the reliability of the product and control the reflection visibility of the metal at the outer edge (or in the via hole region) of the photovoltaic unit, the taper angle of the insulating layer 50 needs to be 35° to 75°.

The insulating layer 50 in the embodiment of the present disclosure is preferably an organic photosensitive material, and may also use inorganic materials such as SiO₂, SiNx, and α-Si. A manufacturing flow when the insulating layer 50 uses the organic photosensitive material includes: S1 coating; S2 pre-curing; S3 exposure; S4 development; and S5 main curing. During the manufacturing of the organic photosensitive material, a fading step may be further included between development and main curing.

A manufacturing flow when the insulating layer 50 uses the inorganic materials such as SiO₂, SiNx, and α-Si includes: S1 chemical vapor deposition (CVD) film formation/magnetron sputtering film formation; S2 PR coating; S3 pre-curing; S4 exposure; S5 development; S6 chemical dry etching; and S7 film stripping.

In the manufacturing of the thin film solar cell according to Embodiment I of the present disclosure, different process conditions need to be formulated according to different types and characteristics of materials to meet the requirements of this angle. When a negative organic photosensitive material is used, the exposure and main curing conditions in the manufacturing flow are the key factors that affect the taper angle. In general, compared to normal exposure process parameters, this process is that when a relatively small exposure amount is selected, a smaller taper angle may be obtained; conversely, when a relatively high exposure amount is selected, a larger (steep) taper angle may be obtained. When positive photoresist is used, the relationship between the setting of an exposure parameter and the size of the taper angle is opposite to this rule. Within an allowable temperature range of device structures and materials, as the main curing temperature increases and the time prolongs, the taper angle will also be appropriately reduced (the slope becomes slower).

When the insulating layer 50 is manufactured by using an inorganic material and a chemical dry etching method, it is necessary to appropriately adjust the film formation rate of CVD and the rate of chemical dry etching to obtain a desired angle. When a relatively small taper angle needs to be obtained, it is necessary to gradually increase a deposition spacing and a deposition pressure value of a CVD chamber (the film formation rate is high after the increase) according to the process of a film layer from thin to thick, so that the film layer gradually becomes loose. During the chemical dry etching, the insulating layer 50 that is etched at first is easier to etch, and the insulating layer 50 close to one side of the front electrode 20 is denser in film quality, so that the amount of etching becomes small, and a final etching anisotropic result forms a relatively small taper angle.

If it is desired to obtain a relatively large taper angle, the increase degree of the deposition spacing and the deposition pressure value of the CVD chamber will be correspondingly reduced, and the density of the film layer that is etched away at first is improved, thereby obtaining a desired result.

As a further improvement of the present disclosure, before the front electrode 20 is manufactured, the method further includes that: a cover layer of an inter-cell dividing line is manufactured on the transparent substrate 10, and the dividing line is configured to divide a plurality of thin film solar cells connected in series.

As a further improvement of the present disclosure, after the metal auxiliary electrode 60 is manufactured (after the step S6), the method further includes that: an anti-reflection layer is manufactured. The anti-reflection layer covers the metal auxiliary electrode 60 to prevent the metal auxiliary electrode 60 from reflecting light.

It should be understood that the manufacturing of the thin film solar cell further includes that: an outermost protective layer is manufactured. The protective layer is configured to protect the back electrode 40, the light absorption layer 30, the front electrode 20, and the metal auxiliary electrode 60. The protective layer may be manufactured by any conventional means in the prior art, which is not specifically described and limited in the present embodiment.

The manufacturing methods of the front electrode 20, the light absorption layer 30, the back electrode 40, the metal auxiliary electrode 60, the insulating layer 50, the cover layer of the inter-cell dividing line and the anti-reflection layer described in Embodiment I of the present disclosure can be any one of the prior art, so that details will not be described repeatedly. The opening structures on the light absorption layer 30, the back electrode 40, and the insulating layer 50 are formed according to their respective processes, and the present disclosure does not specifically limit this.

### Embodiment II

As shown in FIG. 1 to FIG. 3, Embodiment II of the present disclosure provides a thin film solar cell. The thin film solar cell is disposed on one side of a display surface of a display module, and includes a transparent substrate 10, and a photovoltaic unit disposed on the transparent substrate 10 and facing the display module. The photovoltaic unit includes a front electrode 20 disposed on the transparent substrate 10, a light absorption layer 30 disposed on the front electrode 20, and a back electrode 40 disposed on the light absorption layer 30.

The thin film solar cell further includes an insulating layer 50 and a metal auxiliary electrode 60. The insulating layer 50 covers the back electrode 40 and the light absorption layer 30, and extends to be in contact connection with the front electrode 20. The metal auxiliary electrode 60 is in contact connection with the front electrode 20, and extends onto the insulating layer 50. A taper angle is formed between a periphery of the insulating layer 50 and the front electrode 20, and ranges from 35° to 75°.

According to the thin film solar cell of the embodiment of the present disclosure, by the setting of the angle range of the taper angle of the insulating layer, it can be simultaneously ensured that a maximum photovoltaic absorption area and the lowest reflection visibility of the metal auxiliary electrode 60 are obtained.

As shown in FIG. 4 to FIG. 5, as a further improvement of Embodiment 2 of the present disclosure, the back electrode 40 and the light absorption layer 30 are also perforated to form a via hole region, and the insulating layer 50 extends to be in contact with the front electrode 20 in the via hole region.

As a further improvement of Embodiment II of the present disclosure, the insulating layer 50 is not fully filled in the via hole region and the metal auxiliary electrode 60 is in contact with the front electrode 20 in the via hole region. In this way, a contact area of the insulating layer 50 and the front electrode 20 can be enlarged, and the resistance of the front electrode 20 can be further reduced.

As a further improvement of Embodiment II of the present disclosure, an anti-reflection layer (not shown in the figure) is also disposed on the metal auxiliary electrode 60, and the anti-reflection layer covers the metal auxiliary electrode 60.

The thin film solar cell of the embodiment of the present disclosure may be applied by means of single cells, or may be applied by means of a plurality of cells connected in series, and the present disclosure is not particularly limited. When a plurality of thin film solar cells connected in series are applied, inter-cell dividing lines are also disposed between the thin film solar cells.

In the present embodiment, the front electrode 20 may use, but not limited to, metal oxide materials such as SnO₂, ITO, AZO, BZO, GZO or ZnO.

The back electrode 40 preferably use a single-layer electrode film or a multi-layer electrode film, and may use, but not limited to, a monomer metal material, an alloy material or a metal oxide/nitride/halide material and the like. Metal elements contained in the monomer metal materials, alloy materials or metal oxide/nitride/halide materials are one of gold, silver, copper, aluminum, nickel or molybdenum with relatively low electrical resistivity.

It should be finally noted that: the above embodiments are only used to describe the technical solutions of the embodiments of the present disclosure, and not intended to limit the present disclosure. Although the embodiments of the present disclosure has been described in detail with reference to the preferred embodiments, those of ordinary skilled in the art should understand that they can still make modifications or equivalent replacements to the technical solutions of the embodiments of the present disclosure, and the modifications or equivalent replacements do not cause the modified technical solutions to depart from the scopes of the technical solutions of the embodiments of the present disclosure, either.

1. A manufacturing method of a thin film solar cell, characterized in that the manufacturing method comprises the following steps:
step S100: providing a transparent substrate, and stacking a front electrode, a light absorption layer and a back electrode on one side of the transparent substrate facing a display module in sequence to form a film;
step S200: etching the back electrode, the light absorption layer and the front electrode in sequence;
step S300: manufacturing an insulating layer by the film-forming on the back electrode, wherein the insulating layer covers the back electrode and the light absorption layer and extends to be in contact connection with the front electrode; and
step S400: performing film formation and etching on a metal auxiliary electrode on the insulating layer, wherein the metal auxiliary electrode extends to be in contact with the front electrode;
wherein, in the manufacturing process of the insulating layer, a taper angle is formed between a periphery of the insulating layer and the front electrode, and the taper angle ranges from 35° to 75°.

2. The manufacturing method of a thin film solar cell according to claim 1, characterized in that in the step S200, the back electrode and the light absorption layer are further perforated to form a via hole region, and in the step S300, the insulating layer extends to be in contact with the front electrode in the via hole region.

3. The manufacturing method of a thin film solar cell according to claim 2, characterized in that the insulating layer is not fully filled in the via hole region, so that the metal auxiliary electrode is in contact with the front electrode in the via hole region.

3. (canceled)

4. The manufacturing method of a thin film solar cell according to claim 1, characterized in that after the metal auxiliary electrode is manufactured, the method further comprises: manufacturing an anti-reflection layer, wherein the anti-reflection layer covers the metal auxiliary electrode.

5. A thin film solar cell, characterized in that the thin film solar cell comprises a transparent substrate and a photovoltaic unit disposed on the transparent substrate and facing a display module,
the photovoltaic unit comprises a front electrode disposed on the transparent substrate, a light absorption layer disposed on the front electrode, and a back electrode disposed on the light absorption layer,
the thin film solar cell further comprises a metal auxiliary electrode and an insulating layer, wherein the insulating layer covers the back electrode and the light absorption layer, and extends to be in contact connection with the front electrode, the metal auxiliary electrode is in contact connection with the front electrode, and extends onto the insulating layer,
a taper angle is formed between a periphery of the insulating layer and the front electrode, and the taper angle ranges from 35° to 75°.

6. The thin film solar cell according to claim 5, characterized in that the back electrode and the light absorption layer are further perforated to form a via hole region, and the insulating layer is in contact connection with the front electrode in the via hole region.

7. The thin film solar cell according to claim 6, characterized in that the insulating layer is not fully filled in the via hole region, and the metal auxiliary electrode is in contact with the front electrode in the via hole region.

8. The thin film solar cell according to claim 5, characterized in that an anti-reflection layer is further disposed on the metal auxiliary electrode, and the anti-reflection layer covers the metal auxiliary electrode.

9. The manufacturing method of a thin film solar cell according to claim 1, characterized in that before the front electrode is manufactured, the method further comprises: manufacturing a cover layer of an inter-cell dividing line of the transparent substrate.

10. The thin film solar cell according to claim 6, characterized in that an anti-reflection layer is further disposed on the metal auxiliary electrode, and the anti-reflection layer covers the metal auxiliary electrode.

11. The thin film solar cell according to claim 7, characterized in that an anti-reflection layer is further disposed on the metal auxiliary electrode, and the anti-reflection layer covers the metal auxiliary electrode.
